(19) United States
(12) Patent Application Publication
(10) Pub. No.: US 2011/0193095 A1
(43) Pub. Date: Aug. 11, 2011

(54) SEMICONDUCTOR DEVICE AND METHOD FOR FORMING THE SAME

(75) Inventors: Ken Nakata, Kanagawa (JP); Seiji Yaegashi, Kanagawa (JP)

(73) Assignee: SUMITOMO ELECTRIC DEVICE INNOVATIONS, INC., Yokohama-shi (JP)

(21) Appl. No.: 13/087,945

(22) Filed: Apr. 15, 2011

Related U.S. Application Data
(63) Continuation of application No. PCT/JP2009/067804, filed on Oct. 14, 2009.

(30) Foreign Application Priority Data
Oct. 16, 2008 (JP) 2008-267910

(51) Int. Cl. H01L 29/78; H01L 21/20; H01L 29/20

(52) U.S. Cl. 257/76; 438/478; 257/E21.09; 257/E29.255; 257/E29.089

(57) ABSTRACT

A semiconductor device includes a GaN-based semiconductor layer formed on a substrate, a gate insulating film that is formed on a surface of the GaN-based semiconductor layer and is made of aluminum oxide, and a gate electrode formed on the gate insulating film, the gate insulating film having a carbon concentration of 2×10²⁰/cm³ or less.

### CROSS-REFERENCE TO RELATED APPLICATION

This application is based upon and claims the benefit of priority of the prior Japanese Patent Application No. 2008-267910, filed on Oct. 16, 2008, and is a continuation application of PCT/JP2009/067804, filed on Oct. 14, 2009, the entire contents of which are incorporated herein by reference.

### BACKGROUND

(i) Technical Field

A certain aspect of the embodiments discussed herein is related to a semiconductor device and a method for forming a semiconductor device.

(ii) Related Art

Attention has been given to FETs (Field Effect Transistors) using a compound semiconductor including Ga (gallium) and N (nitrogen) (GaN-based semiconductor) as RF high power amplifier devices that operate at high frequencies (RF) and output high power. The GaN-based semiconductor is a semiconductor including gallium nitride (GaN), and is, for example, AlGaN that is a mixed crystal of GaN and aluminum nitride (AlN), InGaN that is a mixed crystal of GaN and indium nitride (InN), AlInGaN that is a mixed crystal of GaN, AlN and InN, or the like.

As an FET using the GaN-based semiconductor, there is known an FET having a gate insulating film between a GaN-based semiconductor layer and a gate electrode (MISFET: Metal Insulator Semiconductor FET) (see Japanese Patent Application Publication 2006-286942). The gate insulating film is capable of suppressing a leakage current between the gate electrode and the semiconductor layer of the MISFET.

It is known to use aluminum oxide formed by an ALD (Atomic Layer Deposition) method as the gate insulating film of MISFET using the GaN-based semiconductor (see, for example, Applied Physics Letters 86, 063501 (2005)). The ALD method alternately introduces source gases in a reaction chamber to grow single-atom thick layers. In a case where aluminum oxide is grown by the ALD method, TMA (Tri methyl Aluminum) is supplied to a substrate and absorbed thereto. Next, TMA is purged. Then, H₂O is supplied to the substrate and is reacted with TMA absorbed to the substrate. Thereafter, purging is performed. Through a series of steps described above, a single-atom thick layer is formed. The ALD method repeats the series of steps to form the desired films. The ALD method makes it possible to grow an insulating film such as an aluminum oxide film, which has a difficulty in growing by CVD (Chemical Vapor Deposition).

However, the gate insulating film formed by the ALD method has impurities therein, which may increase leakage current and may make the FET characteristics unstable.

According to an aspect of the present invention, there is provided a semiconductor device capable of suppressing leakage current in the gate insulating film and having stabilized FET characteristics.

According to another aspect of the present invention, there is provided a semiconductor device includes a GaN-based semiconductor layer formed on a substrate, a gate insulating film that is formed on a surface of the GaN-based semiconductor layer and is made of aluminum oxide, and a gate electrode formed on the gate insulating film, the gate insulating film having a carbon concentration equal to or less than 2×10²⁰/cm³ or less.

### BRIEF DESCRIPTION OF THE DRAWINGS

FIG. 1 is a cross-sectional view of samples used in an experiment;

FIG. 2A is a flowchart of a process for forming an insulating film in a sample A, and FIG. 2B is a flowchart of a process for forming an insulating film in a sample B;

FIG. 3 is a graph that illustrates a relationship between leakage current and the concentration of carbon in an insulating film;

FIG. 4 is a graph that illustrates a relationship between leakage current and an electric field;

FIGS. 5A through 5F are cross-sectional views that illustrate a method for fabricating an FET in accordance with a first embodiment; and

FIG. 6 is a cross-sectional view of an FET in accordance with a second embodiment.

### DETAILED DESCRIPTION

A description will now be given of an experiment conducted by the inventors. The experiment prepared a sample A configured in accordance with a first embodiment, and a sample B for comparison.

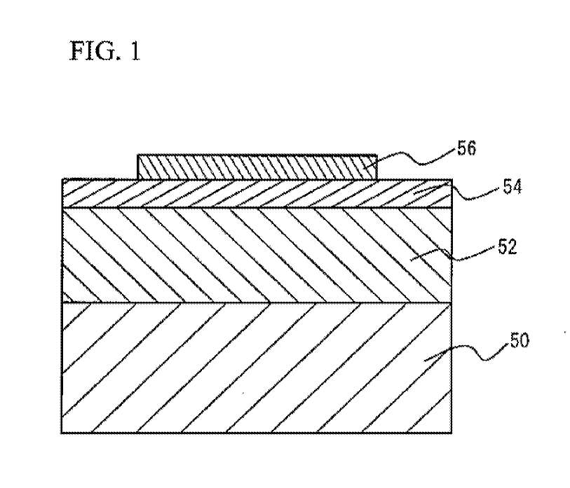

FIG. 1 is a cross-sectional view of samples A and B used in the experiment. Referring to FIG. 1, a GaN-based semiconductor layer 52 composed of GaN is formed on a substrate 50 by MOCVD (Metal Organic CVD). An Al₂O₃ film is formed on the GaN-based semiconductor layer 52 as an insulating film 54. An electrode 56 made of Ni/Au is formed on the insulating film 54 in which Ni underlies Au. As will be described later, the samples A and B differ from each other in the process for forming the insulating film 54, and the other conditions are the same.

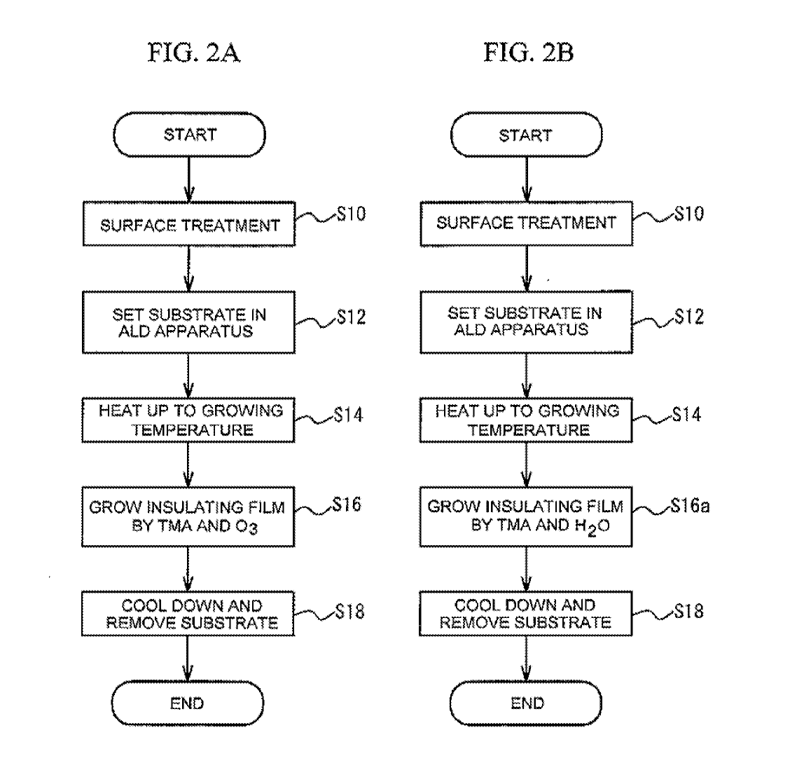

FIG. 2A is a flowchart of a process for forming the insulating film 54 of the sample A, and FIG. 2B is a flowchart of a process for forming the insulating film 54 of the sample B. Referring to FIG. 2A, first, the surface of the GaN layer formed on the substrate 50 is treated in the following sequence (step S10). That is, the surface treatment includes (1) cleanup of organic pollution by a mixture of sulfuric acid and hydrogen peroxide water, (2) cleanup of particle pollution using a mixture of ammonia and hydrogen peroxide water, and (3) cleanup by ammonia water heated at approximately 40° C. Next, the substrate 50 is disposed in the ALD apparatus (step S12). Then, nitrogen gas is introduced in the ALD apparatus as a carrier gas, and is heated up to 400° C., which is the growing temperature (step S14)

Subsequently, TMA ((CH3)3Al) and O₃ are alternately supplied in the ALD apparatus in order to grow an Al₂O₃ film. In this step, the growing temperature is 400° C., and the pressure is 1 torr. The times during which TMA and O₃ are respectively supplied are 0.3 seconds. Purging by nitrogen gas is carried out for five seconds in switching from TMA to O₃ and switching from O₃ to TMA. One cycle consists of a 0.3-second supply of TMA and a 0.3-second supply of O₃, and 500 cycles are carried out to form the Al₂O₃ insulating film 54 having a thickness of approximately 40 nm. Although O₃ is used as a source of oxygen in step S16, O₂ may be used.

Finally, the substrate is cooled down and is removed from the ALD apparatus (step S18). By the above-described process, the insulating film 54 made of Al₂O₃ is formed on the substrate 50.

The process for forming the insulating film 54 of the sample B in that the sample B uses H2O as a source material of the Al₂O₃ film. That is, in step S16a in FIG. 2B, TMA and H₂O are alternately supplied in the ALD apparatus in order to form the Al₂O₃ film. The other steps (steps S10 through S18) are common to those of the sample A, and a detailed description thereof is omitted here.

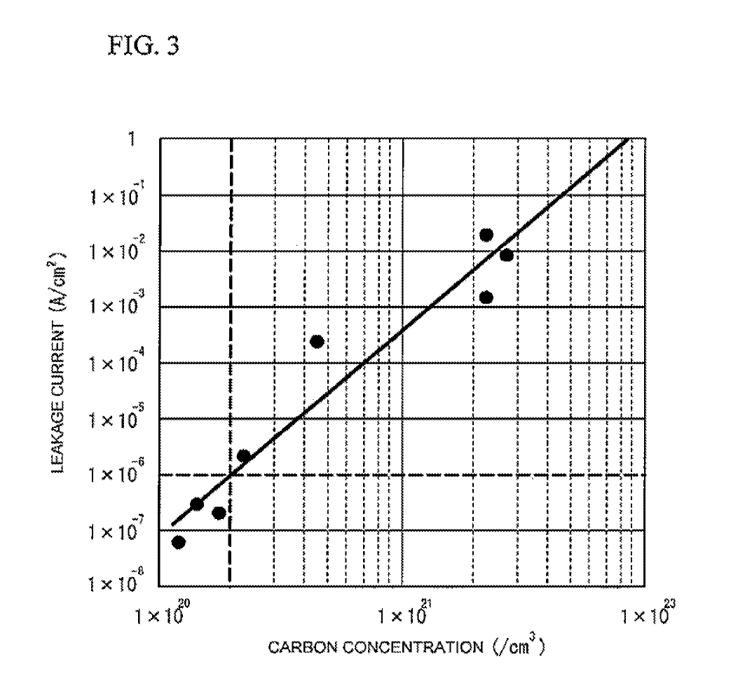

FIG. 3 is a graph of a relationship between the leakage current and the concentration of carbon (C) in the insulating film of Al₂O₃ formed by the ALD method. The leakage current is measured under the condition that a voltage of 3.5 MV is applied to the gate in the forward direction. This voltage is approximately half the breakdown voltage of the FET. The carbon concentration of the insulating film is measured by SIMS (Secondary Ionization Mass Spectrometer). As illustrated in FIG. 3, as the carbon concentration decreases, the leakage current decreases, and the both parameters have a strong correlation. For example, as illustrated in broken lines in FIG. 3, the leakage current is suppressed to 1×10⁻⁶ A/cm² for a carbon concentration equal to or less than 2×10²⁰/cm³.

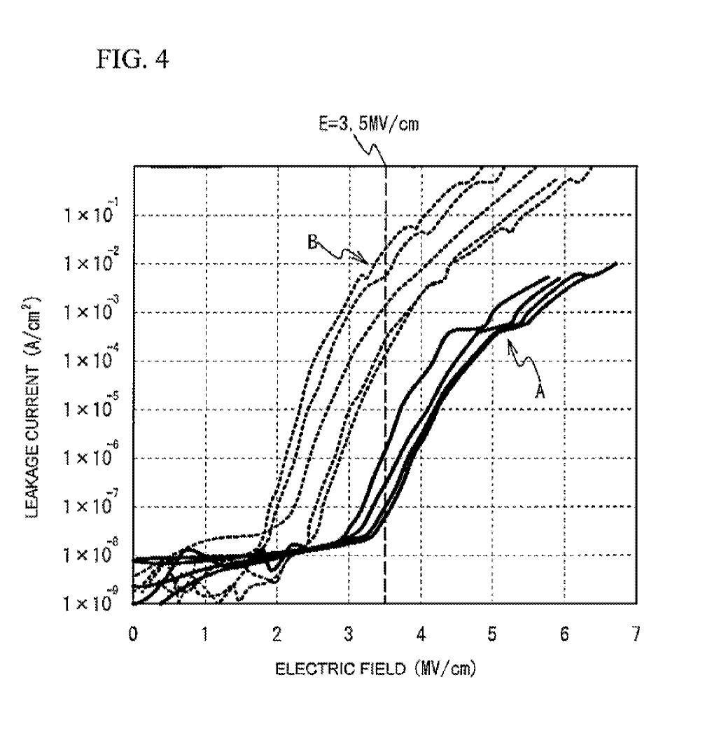

FIG. 4 is a graph of a relationship between the leakage current and the electric field in Al₂O₃ calculated by the forward gate voltage and the Al₂O₃ film thickness in the case where the insulating film 54 is made of Al₂O₃ formed by the ALD method. Solid lines relate to the sample A, and broken lines relate to the sample B. In the experiment, multiple samples A fabricated under the same condition and multiple samples B fabricated under the same condition are prepared (more specifically, four samples A and five samples B) and are measured.

As illustrated, the samples A that use O₃ as the source of the Al₂O₃ film tend to have smaller leakage currents than the samples B that use H₂O as the source of the Al₂O₃ film. For example, when the samples A and B are compared under the condition that E=3.5 MV/cm illustrated in FIG. 3, the samples A have leakage currents of 1×10⁻⁶ A/cm² or lower, while the samples B have leakage currents of 1×10⁻⁴ A/cm² or more. Thus, there is at least a two-order of the magnitude difference in leakage current between the samples A and B.

The above difference may be considered as follows. Carbon contained in the Al₂O₃ film is originated from the methyl group in TMA used as the source. The methyl group of TMA is withdrawn by an oxidation agent supplied together with TMA in step S16 in FIG. 2. O₃ used for the samples A has an oxidation power higher than that of H₂O used for the samples B. Thus, the decomposition reaction of the methyl group of TMA is facilitated and the carbon concentration of the Al₂O₃ film is reduced.

The ALD method has a difficulty in effective removal of impurities, which are typically carbon, because the ALD method grows the insulating film under a relatively gentle condition (a growing temperature of 250 to 400° C.). It is thus considered that the use of O₃ having a high oxidation power for forming the Al₂O₃ film reduces the carbon concentration of the insulating film and suppresses the leakage current. According to an aspect of the present invention, the inventors found out that it is important to consider the relationship between the carbon concentration and the leakage current in the case where aluminum oxide is used as the gate insulating film and to employ a source having a high oxidation power.

Now, some embodiments of FETs having a reduced carbon concentration of the gate insulating film are described.

### First Embodiment

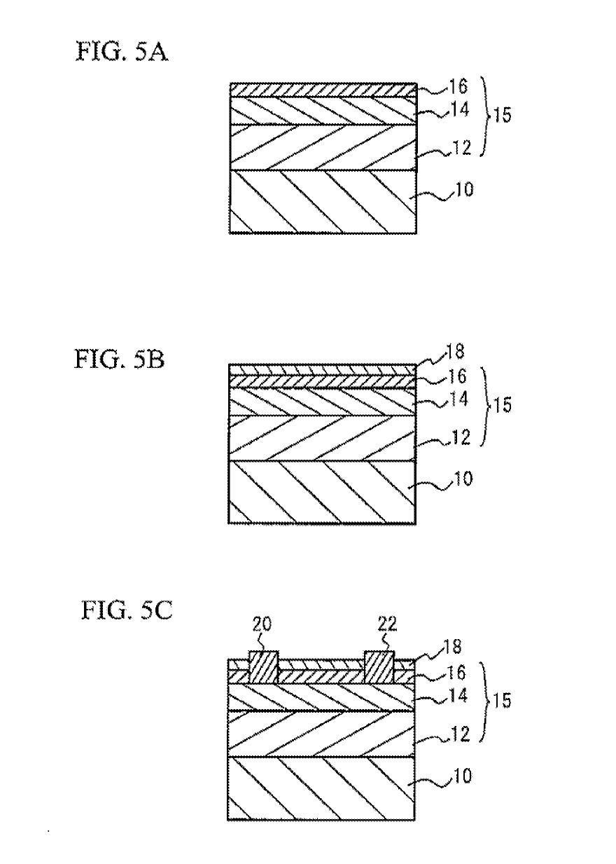

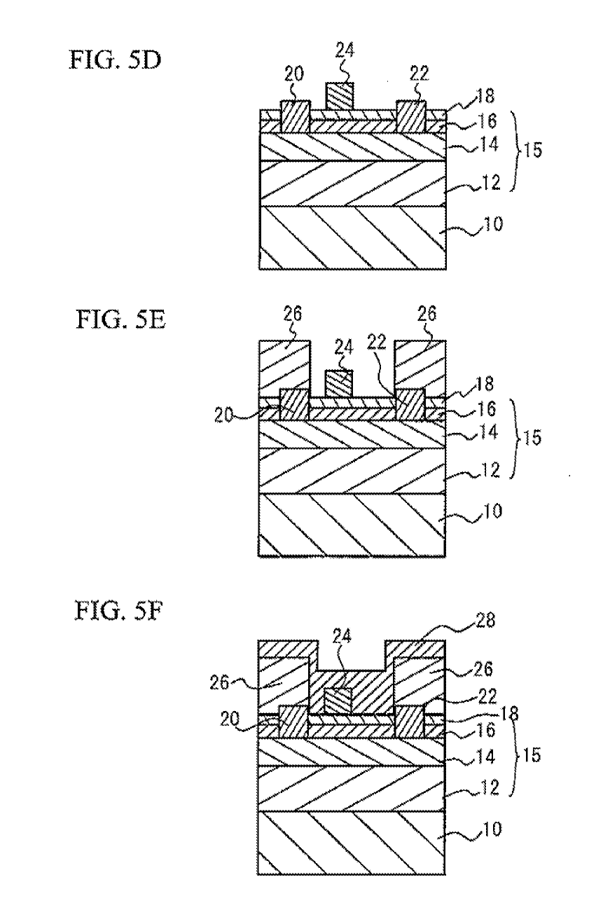

A first embodiment is an exemplary lateral FET. FIGS. 5A through 5F are respectively cross-sectional views that illustrate a method for fabricating a semiconductor device in accordance with the first embodiment. Referring to FIG. 5A, a buffer layer (not illustrated) is formed on a silicon substrate 10 by MOCVD. Next, a GaN channel layer 12 having a thickness of 1000 nm is formed on the buffer layer. Then, an AlGaN electron supply layer 14 having a thickness of 30 nm is formed on the GaN channel layer 12. The Al composition of the AlGaN electron supply layer 14 is 0.2. A GaN cap layer 16 having a thickness of 3 nm is formed on the AlGaN electron supply layer 14. The GaN channel layer 12, the AlGaN electron supply layer 14 and the GaN cap layer 16 define a GaN-based semiconductor layer 15, which is formed on the silicon substrate 10.

Referring to FIG. 5B, a gate insulating film 18 formed by an Al₂O₃ film having a thickness of 40 nm is formed on the GaN-based semiconductor layer 15. The gate insulating film 18 may be formed by the same process as shown in FIG. 2A. That is, the gate insulating film made of Al₂O₃ is formed on the GaN-based semiconductor layer 15 by using TMA and O₃ by the ALD method. Referring to FIG. 5C, an element isolation (not illustrated) is defined by etching using a BCL₃/Cl₂ gas. Then, openings are formed in the gate insulating film 18. A source electrode 20 and a drain electrode 22 each having a Ti/Al structure are respectively formed in the openings.

As illustrated in FIG. 5D, a gate electrode 24 having a Ni/Au structure is formed on the gate insulating film 18. As illustrated in FIG. 5E, Au-based interconnections 26 respectively connected to the source electrode 20 and the drain electrode 22 are formed. As illustrated in FIG. 5F, a protection film 28 that covers the gate electrode 24 and the interconnections 26 is formed. The semiconductor device of the first embodiment is completed through the above process.

As described above, according to the first embodiment, the gate insulating film of Al₂O₃ is formed on the GaN-based semiconductor layer by using TMA and O₃ by the ALD method (step S26 in FIG. 2). It is thus possible to reduce the carbon concentration of the gate insulating film 18 and suppress the leakage current. Therefore, the stabilized FET characteristics can be realized.

The condition for forming the insulating film in step S16 preferably has a carbon concentration of 2×10²⁰/cm³ or less in the insulating film, and more preferably has a carbon concentration of 1×10²⁰/cm³ or less. It is thus possible to further suppress the leakage current and further stabilize the characteristics of FET.

The layer that contacts the gate insulating film 18 of the GaN-based semiconductor layer 15 in the first embodiment is not limited to the GaN layer but may be an AlGaN layer.

### Second Embodiment

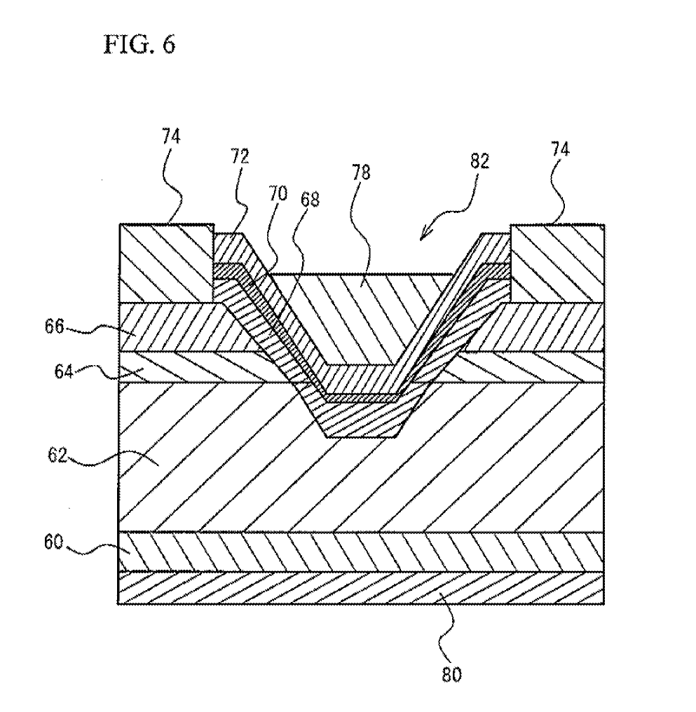

A second embodiment is an exemplary vertical FET. FIG. 6 is a cross-sectional view of the second embodiment. Referring to FIG. 6, on a conductive SiC substrate 60, there are formed an n-type GaN drift layer 62, a p-type GaN barrier layer 64, and an n-type GaN cap layer 66. An opening 82 is formed in these layers so as to reach the drift layer 62. As regrown layers formed so as to cover the opening 82, there are provided a GaN channel layer 68 with no impurity being doped, and an AlGaN electron supply layer 70. A gate insulating film 72 is formed on the electron supply layer 70. The gate insulating film 72 is formed by the process illustrated in FIG. 2A. A source electrode 74 is formed on the GaN cap layer 66 along the opening 82, and a gate electrode 78 is formed in the opening 82. A drain electrode 80 is provided on the back surface of the SiC substrate 60.

The FET may be a lateral FET like the first embodiment in which the source electrode 20 and the drain electrode 22 are provided on the GaN-based semiconductor layer 15 so as to interpose the gate electrode 24. Like the second embodiment, the FET may be a vertical FET in which the source electrode 74 is formed on the n-type GaN cap layer 66 and the drain electrode 80 is provided on the surface of the conductive substrate 60 opposite to the surface thereof on which the GaN-based semiconductor layer is formed.

In the first and second embodiments, the GaN-based semiconductor layer is formed in the MOCVD apparatus by the MOCVD method. The gate insulating film may be formed by forming the GaN-based semiconductor layer on the substrate and performing the ALD method in which the material gas of the MOCVD apparatus is changed to TMA and O₃ without removing the substrate from the MOCVD apparatus. Thus, the much better gate insulating material may be obtained. Although the first and second embodiments employ O₃, O₂ may be used.

Although the first embodiment employs the silicon substrate and the second embodiment employs the SiC substrate, a sapphire substrate or a GaN substrate may be employed.

Although some preferred embodiments of the present invention have been described, the present invention is not limited to the specifically described embodiments but may include various embodiments and variations within the scope of the claimed invention.

What is claimed is:

1. A semiconductor device comprising:
a GaN-based semiconductor layer formed on a substrate;
a gate insulating film in contact with a surface of the GaN-based semiconductor layer and is made of aluminum oxide formed by an ALD apparatus; and
a gate electrode formed on the gate insulating film, the gate insulating film being made of aluminum oxide and having a carbon concentration equal to or less than 2×10²⁰/cm³.

2. The semiconductor device according to claim 1, further comprising a source electrode and a drain electrode that are formed on the surface of the GaN-based semiconductor layer and interpose the gate electrode.

3. The semiconductor device according to claim 1, further comprising:
a source electrode formed on the surface of the GaN-based semiconductor layer; and
a drain electrode formed on another surface of the substrate opposite to the surface on which the GaN-based semiconductor layer is formed.

4. The semiconductor device according to claim 1, wherein the carbon concentration of the gate insulating film is equal to or less than 1×10²⁰/cm³.

5. A method for forming a semiconductor device comprising:
forming a GaN-based semiconductor layer on a substrate;
forming a gate insulating film in contact with the GaN-based semiconductor layer using an ALD apparatus; and
forming a gate electrode on the gate insulating film,
a carbon concentration of the gate insulating film being equal to or less than 2×10²⁰/cm³.

6. The method according to claim 5, wherein the ALD apparatus forms the gate insulating film by alternately introducing source gases in a reaction chamber to grow a single-atom layer by an alternate cycle.

7. The method according to claim 6, wherein eh source gases are TMA and ozone.

8. The method according to claim 7, further comprising introducing nitrogen gas at the time of change of TMA and ozone.

9. The method according to claim 5, wherein the carbon concentration of the gate insulating film is equal to or less than 1×10²⁰/cm³.
